(19) United States
(12) Patent Application Publication
(10) Pub. No.: US 2023/0259035 A1
(43) Pub. Date: Aug. 17, 2023

(54) CHARACTERIZATION OF PHOTOSENSITIVE MATERIALS

(71) Applicant: Applied Materials, Inc., Santa Clara, CA (US)

(72) Inventors: Paola DE CECCO, Santa Clara, CA (US); Ruiying HAO, Santa Clara, CA (US); Regina Germanie FREED, Los Altos, CA (US); Luisa BOZANO, Santa Clara, CA (US)

(21) Appl. No.: 18/093,121

(22) Filed: Jan. 4, 2023

Related U.S. Application Data
(60) Provisional application No. 63/309,370, filed on Feb. 11, 2022.

(51) Int. Cl. G03F 7/20; G03F 7/16; G03F 7/004; G03F 7/40

(52) U.S. Cl. CPC G03F 7/203; G03F 7/2004; G03F 7/167; G03F 7/0043; G03F 7/40

(57) ABSTRACT

Embodiments of the present disclosure generally relate to methods for providing real-time characterization of photoresist properties. In some embodiments, a method of preparing a patterned photoresist on a substrate includes forming an unpatterned photoresist on the substrate, exposing the unpatterned photoresist to a first dose of EM radiation at a first location on the unpatterned photoresist with a first light source, and measuring an optical property of the unpatterned photoresist and exposing the unpatterned photoresist to a second dose of EM radiation at the first location on the unpatterned photoresist to create a patterned or partially patterned photoresist. The second dose of EM radiation has a greater wavelength, a greater number of pulses, or a longer exposure period than the first dose of EM radiation with a second light source. Also, at least one of the first light source and the second light source is an on-board metrology device.

### CROSS-REFERENCE TO RELATED APPLICATIONS

This application claims benefit to U.S. Appl. No. 63/309,370, filed on Feb. 11, 2022, which is herein incorporated by reference.

### BACKGROUND

### Field

Embodiments of the present disclosure generally relate to photosensitive materials, and more specifically, photoresist technology and methods for characterizing photoresist properties.

### Description of the Related Art

Integrated circuits have evolved into complex devices that can include millions of components (e.g., transistors, capacitors and resistors) on a single chip. Photolithography may be used to form components on a chip. Generally the process of photolithography involves forming a photoresist layer on a substrate. The photoresist layer may be formed by, for example, spin-coating. After deposition of the photoresist, a substrate is transferred to a process chamber for exposure. During an exposure stage, a photomask or reticle may be used to selectively expose certain regions of the photoresist layer disposed on the substrate to electromagnetic (EM) radiation, such as EM radiation in the ultraviolet (UV) or extreme ultraviolet (EUV) regions, with a first EM source. Often, more than one exposure subprocess may occur whereby multiple sections of the photoresist layer disposed on the substrate are each exposed to a distinct dose of EM radiation. A dose of EM radiation may include its size (frequency or wavelength) as well as its longevity.

After exposure, the substrate may be heated in a post-exposure bake and develop process whereby any uncrosslinked photoresist is removed. After a post-exposure bake and develop process, another EM source is used to measure the optical properties of the photoresist film at multiple locations corresponding to each of the different doses of EM radiation exposed to the photoresist film. However, current methods which utilize X-ray and optical metrology techniques to measure optical properties of an unexposed or partially exposed photoresist suffer the limitation that the resist will be changed into a different chemical compound when exposed to wavelengths under 400 nm, such as the wavelengths in a UV or EUV tool. Longer wavelengths, on the other hand, such as wavelengths over 400 nm, have low sensitivity to resolve the optical or material properties of the material, hence providing limited insight into the optical or material properties of interest for predicting the behavior of the photoresist film.

The measured optical or material properties can be compared with a contrast curve analysis depicting the variation of the thickness or other optical or material property of the photoresist, prior to a post exposure/bake and develop, as a function of the dose of EM radiation received. However, as described above, the currently known process requires the use of multiple EM sources in different chambers in order to achieve these results. The current process also fails to account for, or separate, the effect of the dose of EM radiation from the initial non-uniformities within the photoresist due to inconsistencies in a deposition process.

FIG. 1 depicts a prior art method 100 of preparing a patterned photoresist on a substrate. At operation 110, an unpatterned photoresist, such as a metallic photoresist, is deposited over a substrate, often with a spin-on deposition process. At operation 120, the substrate is transferred to a second chamber and exposed to a number of doses of EM radiation by a first EM source each dose corresponding to a different location on the unpatterned photoresist in order to pattern the photoresist. The EM radiation from the first EM source may have wavelength of about 400 nm or greater. At operation 130, the substrate is transferred into a third chamber and a post-exposure bake and development process is performed. At operation 140, a second EM source measures the remaining thickness at a number of locations on the patterned photoresist. Where each location corresponds to a distinct dose of EM radiation.

In the prior art method 100 of FIG. 1, described above, the result of the measurement of change in the optical or material property of the patterned photoresist of operation 140 cannot be attributed solely to the EM radiation dose received. This is due to the confounding factor of initial photoresist non-uniformity from operation 110, since each EM radiation dose, and each subsequently changed, measured optical or material property of the photoresist, were taken at distinct locations. Additionally, the EM sources which perform the task of measuring the optical or material property of the photoresist often affect these very properties of the photoresist during the measurement process.

Therefore, there is need for an improved method for providing characterization of photoresist properties during a photolithography process.

### SUMMARY

Embodiments of the present disclosure generally relate to photosensitive materials, and more specifically photoresist technology and methods for providing real-time characterization of photoresist properties throughout post deposition operations, including exposure, bake, and development processes.

In one or more embodiments, a method of preparing a patterned photoresist on a substrate is provided and includes forming an unpatterned photoresist on the substrate, exposing the unpatterned photoresist to a first dose of electromagnetic (EM) radiation at a first location on the unpatterned photoresist with a first light source, and measuring an optical property of the unpatterned photoresist and exposing the unpatterned photoresist to a second dose of EM radiation at the first location on the unpatterned photoresist to create a patterned or partially patterned photoresist. The second dose of EM radiation has a greater wavelength, a greater number of pulses, or a longer exposure period than the first dose of EM radiation with a second light source. Also, at least one of the first light source and the second light source is an on-board metrology (OBM) device.

In other embodiments, a method of preparing a patterned photoresist on a substrate is provided and includes forming an unpatterned photoresist on a substrate, exposing the unpatterned photoresist to a first dose of UV light at a first location on the photoresist with a first light source to create a patterned or partially patterned substrate, the first dose of UV light lasting less than or equal to about 1 millisecond, and measuring an optical property of the photoresist at the first location. The method further includes exposing the patterned or partially patterned photoresist to a second dose of UV light at the first location on the photoresist, the second dose of UV light having a greater wavelength, a greater number of pulses, or a longer exposure period than the first dose of UV light with the first light source.

In some embodiments, a method of preparing a patterned photoresist on a substrate is provided and includes forming an unpatterned photoresist on a substrate, exposing the unpatterned photoresist to a first dose of EM radiation at a first location on the unpatterned photoresist with a first light source, and measuring an optical property of the unpatterned photoresist. The method further includes exposing the unpatterned photoresist to a second dose of EM radiation at the first location on the unpatterned photoresist to create a patterned or partially patterned photoresist and analyzing the optical property of the patterned or partially patterned photoresist as a function of the dose of EM radiation received. The method also includes exposing the patterned or partially patterned photoresist to a third dose of EM radiation at the first location on the patterned or partially patterned photoresist with the first light source, the third dose of EM radiation the same as the first dose of EM radiation, measuring the optical property of the patterned or partially patterned photoresist, and exposing the patterned or partially patterned photoresist to a fourth dose of EM radiation at the first location on the patterned or partially patterned photoresist, the fourth dose of EM radiation different than the second dose of EM radiation.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 depicts a prior art method of characterizing a photoresist by its contrast curve.

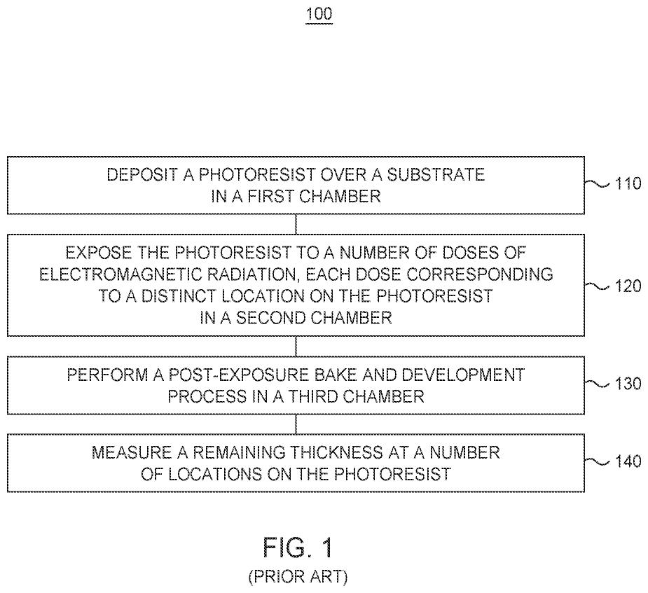

FIG. 2 depicts a method of characterizing a photoresist, according to one or more embodiments described and discussed herein.

FIG. 3 depicts a cross-sectional view of a portion of an integrated circuit during a photolithography process, according to one or more embodiments described and discussed herein.

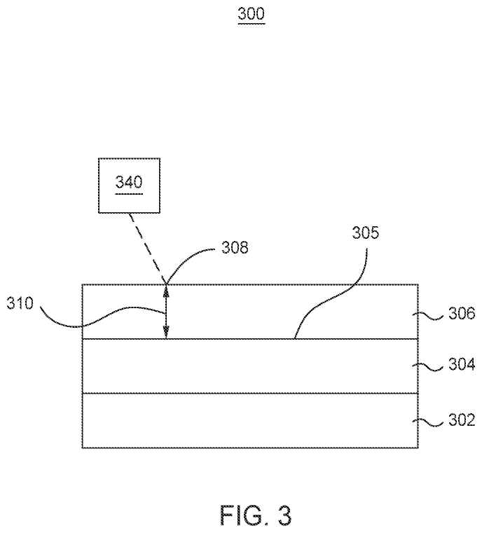

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

According to the embodiments described and disclosed herein, a method for measuring optical or material properties of a photoresist during a photolithography process involves the use of a first electromagnetic (EM) source, such as the one utilized in an on-board metrology (OBM) device, or other optical tool. Such an EM source can be a standalone EM source or an on-board EM source, such as an in-situ EM source or an ex-situ EM source (where in-situ and ex-situ, as used herein, refer to position relative to a process chamber). An on-board EM source may advantageously avoid possible contamination issues and allow for monitoring in a high volume production environment. The measured optical or material properties may include the thickness, surface roughness, chemical composition, complex dielectric constant, complex refractive index, defects of the photoresist, stress of the photoresist, other properties of the photoresist, and/or any combination thereof. In some embodiments, a process chamber includes more than one EM source.

The first EM source is used to expose an unpatterned photoresist to a single short pulse of EM radiation and acquire the reflected light in order to measure optical or material properties of the photoresist, such as the film thickness, without substantially changing the optical or material properties of the photoresist. The single shot pulse duration, intensity and spectral composition can be tuned to achieve the best performance based on material characteristics. The photoresist is not changed by exposure to the single short pulse because the dose of EM radiation is too small to alter the chemical and morphological properties of the photoresist. The EM radiation may be any suitable form of EM radiation such as ultraviolet (UV) light, X-rays, Extreme UV (EUV) light, or other suitable forms of EM radiation. In some embodiments, electron beams may also be suitably used in place of or in conjunction with the EM radiation. After exposing the photoresist to the single, short pulse (the characterized first dose) of EM radiation, the first EM source is then used to expose the photoresist to a second dose of EM radiation that can have a greater wavelength range, a higher frequency of pulses, a longer exposure period than the first dose of EM radiation, or any combination thereof. The first dose followed by the second dose may be repeated in a cycle more than one time, until the intended change in the photoresist is achieved and has been measured, such as until the optical or material properties of the photoresist and their evolution is fully, or accurately, characterized. For example, the first dose followed by the second dose may be repeated in a cycle at least 3 times, at least 10 times, at least 20 times, or at least 40 times.

By utilizing the methods described herein, measurements of the optical properties of the photoresist may be collected at the same location of the photoresist, thus eliminating any effect or disturbance that initial deposition non-uniformity has on the changes to optical properties of the photoresist (e.g., the effects of EM radiation dose and dose longevity on the optical properties of the photoresist can be isolated from the effects of initial photoresist non-uniformity on the optical properties of the photoresist). By isolating the effects of dose size and longevity on the photoresist, an immediate correlation between photoresist lithographic performances and small changes in EM radiation dose can be discovered. These correlations can be further exploited to aid in defining and adjusting lithography settings during device production.

Changes in the optical or material properties of the photoresist can inform adjustments in deposition parameters, and/or subsequent process steps, such as exposure dosage, with the goal of improving the lithographic print quality. Exemplary improvements of the lithographic print quality can include critical dimensions (CDs), CD uniformity, line edge roughness (LER), line width roughness (LWR)), dose to size, or any combination thereof. For example, a process gas flow rate over a substrate during a deposition process or an exposure dose or longevity may be increased or decreased to account for the real-time measurements of an optical property of a photoresist on the substrate. Gas flow rates, deposition duration, and deposition temperatures may also be tuned or adjusted based on the measured photoresist properties.

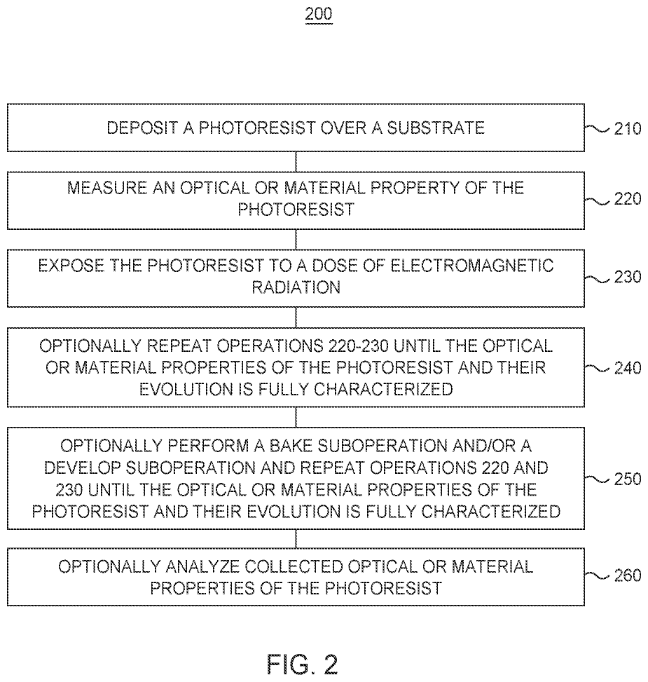

FIG. 2 depicts a method 200 of preparing a patterned photoresist on a substrate according to embodiments of the present disclosure. At operation 210, an unpatterned photoresist film layer 306 is deposited over a substrate 302 in a first processing chamber. The unpatterned photoresist 306 may be formed of any suitable photoresist material. The photoresist material can be or include one or more chemical amplified resists (CARs), one or more photoabsorption resists, one or more metallic materials, one or more metal oxide (MOX) materials, one or more non-metallic materials, or any combination thereof. In some examples, the photoresist 306 contains photoresist materials which can be or include metals, metal oxides, and/or clusters of one or more elements including indium, tin, bismuth, antimony, cesium, molybdenum, hafnium, zirconium iron, cobalt, nickel, copper, zinc, silver, platinum, lead, iodine, tellurium, or any combination thereof. In some embodiments, the photoresist 306 is a dry photoresist. The photoresist may include a positive or negative tone resist resin layer which may include, but is not limited to, acrylates, Novolac resins, poly(methylmethacrylates), and poly(olefin sulfones). The photoresist may also include a photoacid generator which may include, but is not limited to sulfonate compounds, onium salts, introbenzyl esters, s-triazine derivatives, ionic iodonium sulfonates, perfluoroalkanesulfonates, aryl triflates and derivatives and analogs thereof, pyrogallol derivatives, and alkyl disulfones. In one or more examples, upon exposure to EM radiation, the photoacid generator produces or generates one or more charged species which result in latent acid images in the resist resin. In some embodiments, a photomask or reticle may be configured to transfer a pattern containing lines to the photoresist. In other embodiments, a maskless lithography technique may be used.

The photoresist may be deposited by any suitable method, such as a spin-coating process or a vapor deposition process (e.g., a chemical vapor deposition (CVD) process). In a CVD process, two or more precursor gases may be introduced into a process chamber where they mix and react to form amassed polymer material. The precursor gases may be injected in separate gas inlets or a single gas inlet. The precursor gases are injected into the process chamber such that they do not mix until they are over a substrate. In a spin-coating process, the spinning speed can be adjusted to obtain a desired coating thickness. A spin-coating process may advantageously allow for thinner deposited layers necessary for fine patterning. During the spin-coating process, a substrate can be spun at any rate depending on film viscosity and desired thickness for the spun film. In one or example, a substrate can be spun at rates of about 1,000 rotations per minute (rpm) to about 5,000 rpm.

In some embodiments, an optional underlayer 304 is deposited between the substrate 302 and the photoresist 306 such that the underlayer 304 and the photoresist 306 have an interface 305. The interface 305 may play a role in the photoresist lithographic print performances. In some embodiments, such performances can be controlled by choosing an underlayer with a specific band structure and/or dielectric constant. The underlayer can be or include a high-k dielectric layer, a barrier layer, a conductive layer, an interfacial layer, other suitable layers, and/or combinations thereof. The underlayer can be or include one or more materials including one or more carbon-based materials, one or more metal-based materials, one or more oxides, one or more nitrates, one or more silicon-based materials, one or more spin-on-glass (SOG) materials, one or more spin-on-carbon (SOC) materials, one or more antireflective coatings, one or more adhesion-based materials, or any combination thereof.

After operation 210, the substrate 302 may be transferred to a second chamber. At operation 220, the first EM source 340 exposes the unpatterned photoresist 306 to a first dose of EM radiation at a first location 308 on the unpatterned photoresist 306 in order to measure an optical or material property of the photoresist 306 in the second chamber. The optical or material property may include the photoresist thickness 310, surface roughness, chemical composition, complex dielectric constant, complex refractive index, or other optical property of the photoresist 306 and may be determined with ellipsometry, reflectometry, or the fluorescence of photoelectron emittance. The first EM source 340 may be an on-board metrology (OBM) device and may be in-situ or ex-situ. The EM radiation may be any suitable form of EM radiation, such as UV light, X-rays, EUV light, or other suitable forms of EM radiation. In some embodiments, electron beams may also be suitably used in place of or in conjunction with the EM radiation. The first dose of EM radiation is a single short pulse of EM radiation which does not change the optical or material properties of the photoresist 306.

The first dose of EM radiation may have a longevity of less than or equal to about 100 milliseconds, such as less than or equal to about 100 milliseconds, such as less than or equal to about 2 milliseconds, such as less than or equal to about 1 millisecond, such as less than or equal to about 2 microseconds, such as less than or equal to about 1 microsecond. The first dose of EM radiation may have a wavelength of about 13 nm and about 800 nm. In some embodiments, a scanning beam or an imager are also used in order to obtain spatial resolution of the photoresist. For example, a scanning beam or an imager may provide information on surface morphology or defects in the photoresist film.

At operation 230, a second light pulse exposes the unpatterned photoresist 306 to a second dose of EM radiation in the second chamber in order to create a patterned or partially patterned photoresist. In some embodiments, the second light pulse may be emitted by the first EM source 340. In some embodiments, the second light pulse may be emitted by a second EM source (not shown). The second dose of EM radiation covers at least the first location 308 on the photoresist 306. The optical or material properties of the photoresist 306 are changed after the second dose of EM radiation. For example, the thickness 310 of the patterned or partially patterned photoresist 306 after the second dose is lower than the thickness 310 of the unpatterned photoresist 306 before the second dose. The EM radiation of the second dose may be any suitable form of EM radiation, such as UV light, X-rays, EUV light, or other suitable forms of EM radiation. In some embodiments, electron beams may also be suitably used in place of or in conjunction with the EM radiation. In some embodiments, the second dose of EM radiation has one or more of a greater wavelength than the first dose of EM radiation, a higher frequency of pulses than the first dose, and a greater longevity than the first dose.

At optional operation 240, operations 220 and 230 are repeated on the patterned or partially patterned photoresist 306 to collect or otherwise produce a plurality of data points of optical or material properties by operation 220. The collected data points include the measured optical or material properties of the photoresist and the evolution of these properties is fully characterized to produce an accurate contrast curve. Full characterization of the evolution of the measured optical or material properties of the photoresist depends on a number of factors, such as the brightness of the illumination during exposure processes in between measurements. For example, the brighter the illumination during exposure processes in between measurements, the less points that are necessary in order to fully characterize the evolution of the measured optical or material properties of the photoresist. In some embodiments, which can be combined with other embodiments, operations 220 and 230 are repeated between about 30 and about 500 times, such as between about 100 and about 300 times, such as about 150 and 250 times. In some embodiments, operations 220 and 230 can be repeated up to 10 times in less than or equal to about 1 second. It is contemplated that the optical or material property of the photoresist can also be measured during the deposition of the photoresist utilizing the methods described herein.

At optional operation 250, the patterned or partially patterned photoresist 306 is treated with a bake suboperation and/or a develop suboperation where it may be heated in order to remove any uncrosslinked photoresist. Prior to the post-exposure bake suboperation and/or develop suboperation, the patterned substrate 302 may be transferred to a third process chamber. During the post-exposure bake suboperation, the substrate is heated and photoacid generators in the patterned or partially patterned photoresist 306 continue to alter the chemical properties of the exposed portions of the patterned photoresist 306. In one or more embodiments, the patterned or partially patterned photoresist 306 on the substrate is heated to a temperature in a range from about 30° C., about 35° C., about 40° C., about 50° C., about 65° C., about 80° C., or about 100° C. to about 120° C., about 150° C., about 180° C., about 200° C., about 250° C., about 300° C., about 400° C., or greater during the post-exposure bake and/or development process. For example, the patterned or partially patterned photoresist 306 can be heated to a temperature in a range from about 30° C. to about 400° C., about 50° C. to about 400° C., about 50° C. to about 200° C., about 50° C. to about 100° C., about 50° C. to about 80° C., about 100° C. to about 400° C., about 100° C. to about 300° C., about 100° C. to about 250° C., about 100° C. to about 200° C., or about 100° C. to about 150° C. during the post-exposure bake and/or development process. Optionally, during the post-exposure bake suboperation, the pressure of the process chamber may also be reduced by a vacuum source.

In some embodiments during optional operation 250, which can be combined with other embodiments, operations 220 and 230 are repeated between about 30 and about 500 times, such as between about 100 and about 300 times, such as about 150 and 250 times. In some embodiments, operations 220 and 230 can be repeated up to 10 times in less than or equal to about 1 second. It is contemplated that the optical or material property of the photoresist can also be measured during the deposition of the photoresist utilizing the methods described herein.

After the optional post-exposure bake suboperation, the substrate, and, in particular, the photoresist may be developed and rinsed. Depending on the type of photoresist used, regions of the substrate that were exposed to EM radiation may either be resistant to removal or more prone to removal. The patterned or partially patterned photoresist 306 may be developed by, for example, exposing the photoresist to a developer, such as sodium hydroxide solution, a tetramethylammonium hydroxide solution, xylene, or Stoddard solvent. The substrate may be rinsed with, for example, water or n-butylacetate. Optionally, the substrate may be hard-baked and inspected. An optional pre-exposure bake suboperation is also contemplated in order to evaporate or partially evaporate photoresist solvents.

At optional operation 260, the data points of the optical or material property of the patterned or partially patterned photoresist 306, collected by repeating operations 220 and 230, are analyzed in order to create dynamic models of the photoresist. For example, a contrast curve analysis of the photoresist 306 may be created in order to depict the variation in the material or optical property of the photoresist 306 as a function of the dose of EM radiation. In other embodiments, the material or optical property of the photoresist 306 may be viewed as a function of exposure longevity where the dose of EM radiation emanating from the source, such as the first EM source 340, is held constant for different lengths of time during exposure.

Examples of potential data to be collected by the above method include thickness of the photoresist 306 versus dose of EM radiation and/or thickness of the patterned or partially patterned photoresist 306 versus exposure longevity at a constant dose of EM radiation, where thickness may be replaced with any number of optical or material properties of interest of the photoresist. In this way, the time dependent results of the optical property can be analyzed using the trend (e.g., a slope, percentage change, or other critical value) in order to extrapolate the quantity of interest (e.g., the optical or material property) at any time, such as time is equal to zero (e.g., before the exposure process) or, alternatively, time is equal to infinity (e.g., after the photoresist film is fully developed).

Utilizing data collected during the methods described above, subsequent deposition and exposure processes can be altered in order to increase process uniformity. For example, wafer to wafer uniformity can be improved by adjusting the deposition or exposure of subsequent wafers. For example, uniformity within a single wafer can be improved in real-time by adjusting the deposition or exposure characteristics of the wafer based upon the data points of optical properties collected. Deposition characteristics of the wafer may include gas flow rates, deposition duration, and/or deposition temperature. Exposure characteristics of the wafer may include exposure duration and/or exposure temperature. In some examples, deposition or exposure characteristics may be controlled via a tuning knob. It is further contemplated that the gradient of chemical composition of a photoresist can be controlled in real-time by adjusting the deposition or exposure characteristics of the photoresist based upon the data points of optical properties collected.

By utilizing the methods described above, measurements of the optical or material properties of the photoresist may be collected at the same location on the photoresist, thus eliminating any effect or disturbance that initial deposition non-uniformity has on the changes to optical or material properties of the photoresist (e.g., the effects of EM radiation dose and dose over time on the optical or material properties of the photoresist can be isolated from the effects of initial photoresist non-uniformity on the optical or material properties of the photoresist). Additionally, exposure and measurement can be performed in the same chamber, thus leading to less down time during substrate transfer and increasing overall throughput. The methods described herein allow for optical measurement which does not affect the optical or material properties of the photoresist, thus allowing for additional insight into the effects of EM radiation dosage on the optical or material properties of the photoresist. This, in turn, allows for immediate correlation between even small changes in EM radiation dose and photoresist properties.

Additionally, the methods described and discussed herein can be utilized to determine the chemical state of the photoresist 206. In one or more examples, the methods described and discussed herein includes observing the localized energy field of the photoresist 206 and absorbing light reflected by the band gaps in order to approximate chemical states. Furthermore, the methods described and discussed herein allow for the measurement of photoresist sensitivity to an exposure process at different doses or lengths of time without the need of an EUV chamber. Thus, measurements can be made on both patterned and unpatterned wafers both inside and outside of a deposition chamber and rapid pre-screening of new photoresists can take place.

Embodiments of the present disclosure further relate to any one or more of the following examples 1-15:

1. A method of preparing a patterned photoresist on a substrate, comprising: forming an unpatterned photoresist on the substrate; exposing the unpatterned photoresist to a first dose of electromagnetic (EM) radiation at a first location on the unpatterned photoresist with a first light source; measuring an optical property of the unpatterned photoresist; and exposing the unpatterned photoresist to a second dose of EM radiation at the first location on the unpatterned photoresist to create a patterned or partially patterned photoresist, the second dose of EM radiation having a greater wavelength, a greater number of pulses, or a longer exposure period than the first dose of EM radiation with a second light source, wherein at least one of the first light source and the second light source is an on-board metrology (OBM) device.

2. A method of preparing a patterned photoresist on a substrate, comprising: forming an unpatterned photoresist on a substrate; exposing the unpatterned photoresist to a first dose of ultraviolet (UV) light at a first location on the photoresist with a first light source to create a patterned or partially patterned substrate, the first dose of UV light lasting less than or equal to about 1 millisecond; measuring an optical property of the photoresist at the first location; and exposing the patterned or partially patterned photoresist to a second dose of UV light at the first location on the photoresist, the second dose of UV light having a greater wavelength, a greater number of pulses, or a longer exposure period than the first dose of UV light with the first light source.

3. The method according to example 2, wherein the second dose of EM radiation has one or more of a greater wavelength than the first dose of EM radiation.

4. The method according to example 2 or 3, wherein the first dose of EM radiation does not substantially change the measured optical property of the photoresist.

5. A method of preparing a patterned photoresist on a substrate, comprising: forming an unpatterned photoresist on a substrate; exposing the unpatterned photoresist to a first dose of electromagnetic (EM) radiation at a first location on the unpatterned photoresist with a first light source; measuring an optical property of the unpatterned photoresist; exposing the unpatterned photoresist to a second dose of EM radiation at the first location on the unpatterned photoresist to create a patterned or partially patterned photoresist; analyzing the optical property of the patterned or partially patterned photoresist as a function of the dose of EM radiation received; exposing the patterned or partially patterned photoresist to a third dose of EM radiation at the first location on the patterned or partially patterned photoresist with the first light source, the third dose of EM radiation the same as the first dose of EM radiation; measuring the optical property of the patterned or partially patterned photoresist; and exposing the patterned or partially patterned photoresist to a fourth dose of EM radiation at the first location on the patterned or partially patterned photoresist, the fourth dose of EM radiation different than the second dose of EM radiation.

6. The method according to example 5, wherein the fourth dose is chosen based on the correlation between the measured difference in the optical property between the first dose of EM radiation and third dose of EM radiation.

7. The method according to any one of examples 1-6, wherein the first dose of EM radiation comprises ultraviolet (UV) light, X-rays, or Extreme UV (EUV) light.

8. The method according to any one of examples 1-7, wherein the first light source and the second light source are once and the same.

9. The method according to any one of examples 1-8, wherein the first dose of EM radiation has a longevity of less than or equal to 1 millisecond.

10. The method according to any one of examples 1-9, further comprising: analyzing the optical property of the patterned or partially patterned photoresist as a function of the wavelength size or longevity of each dose of EM radiation received; exposing the patterned or partially patterned photoresist to a third dose of EM radiation at the first location on the partially patterned photoresist with the first light source, the third dose of EM radiation the same as the first dose of EM radiation; measuring the optical property of the photoresist; and exposing the patterned or partially patterned photoresist to a fourth dose of EM radiation at the first location on the photoresist to further pattern the partially patterned photoresist, the fourth dose of EM radiation different than the second dose of EM radiation.

11. The method according to any one of examples 1-10, wherein the first dose of EM radiation and the second dose of EM radiation have tunable wavelength and longevity.

12. The method according to any one of examples 1-11, wherein the unpatterned photoresist is a metal oxide photoresist.

13. The method according to any one of examples 1-12, wherein the unpatterned photoresist is formed on the substrate by a chemical vapor deposition (CVD) process or a spin-coating process.

14. The method according to any one of examples 1-13, further comprising heating the patterned or partially patterned photoresist to a temperature in a range from about 30° C. to about 400° C. during a post-exposure bake and/or development process.

15. The method according to any one of examples 1-14, wherein the measured optical property of the photoresist comprises a thickness, a surface roughness, a chemical composition, a complex dielectric constant, or a complex refractive index.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation can be included in any value provided herein.

Certain embodiments and features have been described using a set of numerical minimum values and a set of numerical maximum values. It should be appreciated that ranges including the combination of any two values, e.g., the combination of any minimum value with any maximum value, the combination of any two minimum values, and/or the combination of any two maximum values are contemplated unless otherwise indicated. Certain minimum values, maximum values, and ranges appear in one or more claims below.

What is claimed is:

1. A method of preparing a patterned photoresist on a substrate, comprising:
forming an unpatterned photoresist on the substrate;
exposing the unpatterned photoresist to a first dose of electromagnetic (EM) radiation at a first location on the unpatterned photoresist with a first light source;
measuring an optical property of the unpatterned photoresist; and
exposing the unpatterned photoresist to a second dose of EM radiation at the first location on the unpatterned photoresist to create a patterned or partially patterned photoresist, the second dose of EM radiation having a greater wavelength, a greater number of pulses, or a longer exposure period than the first dose of EM radiation with a second light source, wherein at least one of the first light source and the second light source is an on-board metrology (OBM) device.

2. The method of claim 1, wherein the first dose of EM radiation comprises ultraviolet (UV) light, X-rays, or Extreme UV (EUV) light.

3. The method of claim 1, wherein the first light source and the second light source are once and the same.

4. The method of claim 1, wherein the first dose of EM radiation has a longevity of less than or equal to 1 millisecond.

5. The method of claim 1, further comprising:
analyzing the optical property of the patterned or partially patterned photoresist as a function of the wavelength size or longevity of each dose of EM radiation received;
exposing the patterned or partially patterned photoresist to a third dose of EM radiation at the first location on the partially patterned photoresist with the first light source, the third dose of EM radiation the same as the first dose of EM radiation;
measuring the optical property of the photoresist; and
exposing the patterned or partially patterned photoresist to a fourth dose of EM radiation at the first location on the photoresist to further pattern the partially patterned photoresist, the fourth dose of EM radiation different than the second dose of EM radiation.

6. The method of claim 1, wherein the first dose of EM radiation and the second dose of EM radiation have tunable wavelength and longevity.

7. The method of claim 1, wherein the unpatterned photoresist is a metal oxide photoresist.

8. The method of claim 1, wherein the unpatterned photoresist is formed on the substrate by a chemical vapor deposition (CVD) process or a spin-coating process.

9. The method of claim 1, further comprising heating the patterned or partially patterned photoresist to a temperature in a range from about 30° C. to about 400° C. during a post-exposure bake and/or development process.

10. The method of claim 1, wherein the measured optical property of the photoresist comprises a thickness, a surface roughness, a chemical composition, a complex dielectric constant, or a complex refractive index.

11. A method of preparing a patterned photoresist on a substrate, comprising:
forming an unpatterned photoresist on a substrate;
exposing the unpatterned photoresist to a first dose of ultraviolet (UV) light at a first location on the photoresist with a first light source to create a patterned or partially patterned substrate, the first dose of UV light lasting less than or equal to about 1 millisecond;
measuring an optical property of the photoresist at the first location; and
exposing the patterned or partially patterned photoresist to a second dose of UV light at the first location on the photoresist, the second dose of UV light having a greater wavelength, a greater number of pulses, or a longer exposure period than the first dose of UV light with the first light source.

12. The method of claim 11, wherein the second dose of EM radiation has one or more of a greater wavelength than the first dose of EM radiation.

13. The method of claim 11, wherein the first dose of EM radiation does not substantially change the measured optical property of the photoresist.

14. The method of claim 11, wherein the unpatterned photoresist is a metal oxide photoresist.

15. The method of claim 11, wherein the unpatterned photoresist is formed on the substrate by a chemical vapor deposition (CVD) process or a spin-coating process.

16. The method of claim 11, further comprising heating the patterned or partially patterned photoresist to a temperature in a range from about 30° C. to about 400° C. during a post-exposure bake and/or development process.

17. The method of claim 11, wherein the measured optical property of the photoresist comprises a thickness, a surface roughness, a chemical composition, a complex dielectric constant, or a complex refractive index.

18. A method of preparing a patterned photoresist on a substrate, comprising:
forming an unpatterned photoresist on a substrate;
exposing the unpatterned photoresist to a first dose of electromagnetic (EM) radiation at a first location on the unpatterned photoresist with a first light source;
measuring an optical property of the unpatterned photoresist;
exposing the unpatterned photoresist to a second dose of EM radiation at the first location on the unpatterned photoresist to create a patterned or partially patterned photoresist;
analyzing the optical property of the patterned or partially patterned photoresist as a function of the dose of EM radiation received;
exposing the patterned or partially patterned photoresist to a third dose of EM radiation at the first location on the patterned or partially patterned photoresist with the first light source, the third dose of EM radiation the same as the first dose of EM radiation;
measuring the optical property of the patterned or partially patterned photoresist; and
exposing the patterned or partially patterned photoresist to a fourth dose of EM radiation at the first location on the patterned or partially patterned photoresist, the fourth dose of EM radiation different than the second dose of EM radiation.

19. The method of claim 18, wherein the fourth dose is chosen based on the correlation between the measured difference in the optical property between the first dose of EM radiation and third dose of EM radiation.

20. The method of claim 19, wherein the unpatterned photoresist is a metal oxide photoresist, and wherein the unpatterned photoresist is formed on the substrate by a chemical vapor deposition (CVD) process or a spin-coating process.
